(19) United States
(12) Patent Application Publication
(10) Pub. No.: US 2011/0217845 A1
(43) Pub. Date: Sep. 8, 2011

(54) Polishing Composition and Polishing Method Using The Same

(75) Inventors: Shuhei TAKAHASHI, Nagoya-shi (JP); Hitoshi MORINAGA, Ichinomiya-shi (JP)

(73) Assignee: FUJIMI, INC., Kiyosu-shi (JP)

(21) Appl. No.: 13/035,478

(22) Filed: Feb. 25, 2011

(30) Foreign Application Priority Data
Mar. 2, 2010 (JP) 2010-045676

(51) Int. Cl. H01L 21/306; C09K 13/00

(52) U.S. Cl. 438/693; 252/79.1; 257/E21.23

(57) ABSTRACT

A polishing composition is disclosed containing a nonionic active agent with a molecular weight of 1,000 or more and less than 100,000 and an HLB value of not less than 17, a basic compound, and water. The nonionic active agent is preferably an oxyalkylene homopolymer or a copolymer of different oxyalkylenes. The polishing composition may further contain at least one of silicon dioxide and a water-soluble polymer. The polishing composition is used, for example, in polishing the surface of semiconductor substrates such as silicon wafers.

### BACKGROUND OF THE INVENTION

The present invention relates to a polishing composition used mainly in polishing a semiconductor substrate such as a silicon wafer and a method of polishing a semiconductor substrate using the polishing composition.

Polishing compositions used in polishing semiconductor substrates such as silicon wafers are disclosed in Japanese Laid-Open Patent Publication No. 10-245545, Japanese Laid-Open Patent Publication No. 2001-110760, Japanese Laid-Open Patent Publication No. 2005-85858, and Japanese Patent No. 4212861. Mainly in order to reduce surface haze of a polished semiconductor substrate, the polishing compositions disclosed in Japanese Laid-Open Patent Publication No. 10-245545, Japanese Laid-Open Patent Publication No. 2001-110760, and Japanese Laid-Open Patent Publication No. 2005-85858 contain a copolymer of polyoxyethylene and polyoxypropylene. The polishing composition disclosed in Japanese Patent No. 4212861 contains polyoxyethylene for the same purpose.

However, not a few particles, especially fine particles having sizes below 50 nm adhering to the surface of the semiconductor substrate polished with any polishing composition disclosed in Japanese Laid-Open Patent Publication No. 10-245545, Japanese Laid-Open Patent Publication No. 2001-110760, Japanese Laid-Open Patent Publication No. 2005-85858, and Japanese Patent No. 4212861 were observed in inspection using the latest surface defect inspection apparatus. The cause of adhering particles is considered to be residual copolymers of polyoxyethylene and polyoxypropylene or residual polyoxyethylene on the surface of a semiconductor substrate that was not removed by washing after polishing. It is highly important to suppress the residues of components of the polishing composition and prevent resulting adhesion of particles, in consideration of the increasing demand for semiconductor substrates with fewer defects and higher smoothness.

### SUMMARY OF THE INVENTION

The present invention is based on findings through intensive research by the present inventors that both reducing surface haze of a polished semiconductor substrate and prevention of adhesion of particles to the semiconductor substrate surface can be achieved by using a nonionic active agent having specific ranges of molecular weight and hydrophile-lipophile balance (HLB) value. It is therefore an objective of the present invention to provide a polishing composition that can reduce surface haze of a polished semiconductor substrate and prevent adhesion of particles to the semiconductor substrate surface as well. It is another objective of the present invention to provide a method of polishing a semiconductor substrate using the polishing composition.

In order to achieve the objectives, in accordance with one aspect of the present invention, a polishing composition is provided that contains a nonionic active agent with a molecular weight ranging from 1,000 or more and less than 100,000 and an HLB value of not less than 17, a basic compound, and water.

The nonionic active agent is preferably an oxyalkylene homopolymer or a copolymer of different oxyalkylenes. The oxyalkylene homopolymer or the copolymer of different oxyalkylenes preferably contains oxyethylene units in a proportion of not less than 85% by mass. The polishing composition may further contain at least one of silicon dioxide and a water-soluble polymer. The water-soluble polymer is preferably a cellulose derivative with a weight-average molecular weight of not less than 100,000.

In another aspect of the present invention, a method of polishing a surface of a semiconductor substrate is provided that uses the polishing composition in the aspect described above.

Other aspects and advantages of the invention will become apparent from the following description illustrating by way of example the principles of the invention.

### DETAILED DESCRIPTION OF THE PREFERRED EMBODIMENTS

One embodiment of the present invention will now be described below.

A polishing composition of the present embodiment is prepared by blending a specific nonionic active agent and a basic compound into water preferably together with at least one of silicon dioxide and a water-soluble polymer. Accordingly, the polishing composition contains a nonionic active agent, a basic compound, and water, and preferably further contains at least one of silicon dioxide and a water-soluble polymer. The polishing composition is used mainly in polishing the surface of semiconductor substrates such as silicon wafers, especially in finish polishing of the surface of semiconductor substrates.

### <Nonionic Active Agent>

A nonionic active agent contained in the polishing composition has a function for coating the surface of a semiconductor substrate during polishing to buffer the semiconductor substrate surface from physical polishing action. This function of the nonionic active agent enables reduction of surface haze of the polished semiconductor substrate.

The nonionic active agent for use has a molecular weight of 1,000 or more and less than 100,000 and a hydrophile-lipophile balance (HLB) value of not less than 17. The term HLB value here is defined by Griffin's method. According to Griffin's method, an HLB value is calculated from 20×(the sum total of the molecular weights of hydrophilic moieties)/(the sum total of the molecular weights of the hydrophilic moieties and the molecular weights of the hydrophobic moieties). Examples of the hydrophilic moieties include an oxyethylene group, a hydroxyl group, a carboxyl group, and esters. Examples of the hydrophobic moieties include an oxypropylene group, an oxybutylene group, and an alkyl group.

When a nonionic active agent with a molecular weight of less than 1,000 is used, it is difficult to reduce the surface haze of a polished semiconductor substrate sufficiently. In order to reduce the surface haze of a polished semiconductor substrate to a level particularly suitable for practical use, the nonionic active agent has a molecular weight of preferably not less than 2,000, more preferably not less than 3,000.

When a nonionic active agent with a molecular weight of 100,000 or more is used, it is difficult to suppress adhesion of particles to the polished surface of a semiconductor substrate sufficiently. In order to suppress adhesion of particles to the polished surface of a semiconductor substrate to a level particularly suitable for practical use, the nonionic active agent has a molecular weight of preferably less than 80,000, more preferably less than 50,000.

When a nonionic active agent with an HLB value of less than 17 is used, it is also difficult to suppress adhesion of particles to the polished surface of a semiconductor substrate sufficiently. In order to suppress adhesion of particles to the polished surface of a semiconductor substrate to a level particularly suitable for practical use, the nonionic active agent has an HLB value of preferably not less than 18.

The nonionic active agent for use is preferably an oxyalkylene homopolymer or a copolymer of different oxyalkylenes. In this case, it is easy to reduce the surface haze of a polished semiconductor substrate to a level particularly suitable for practical use. The reason for this is believed that each of the homopolymer and the copolymer has slightly hydrophilic ether bonds and slightly hydrophobic alkylene groups alternately in the molecular chain. Examples of the oxyalkylene homopolymer include polyoxyethylene, polyethylene glycol, polyoxypropylene, and polyoxybuthylene. Examples of the copolymer of different oxyalkylenes include polyoxyethylene-polyoxypropylene glycol and polyoxyethylene-polyoxybuthylene glycol.

The oxyalkylene homopolymer or the copolymer of different oxyalkylenes for use as a nonionic active agent contains oxyethylene units in a proportion of preferably not less than 85% by mass, and more preferably not less than 90% by mass. The higher the proportion of oxyethylene units in the homopolymer or the copolymer, the fewer becomes the number of particles adhering to the polished surface of a semiconductor substrate.

The polishing composition contains preferably not less than 0.0001% by mass, and more preferably not less than 0.001% by mass of the nonionic active agent. The more the amount of contained nonionic active agent, the less becomes the development of surface haze of a polished semiconductor substrate.

The polishing composition contains preferably less than 0.05% by mass, and more preferably less than 0.02% by mass of the nonionic active agent. The less the amount of contained nonionic active agent, the fewer becomes the number of particles adhering to the polished surface of a semiconductor substrate.

### <Basic Compound>

A basic compound contained in the polishing composition has a function for chemically polishing a semiconductor substrate.

In order to enhance the rate of polishing a semiconductor substrate to a level particularly suitable for practical use with the polishing composition, the basic compound for use is preferably ammonia, potassium hydroxide, sodium hydroxide, tetramethylammonium hydroxide, tetraethylammonium hydroxide, ammonium hydrogen carbonate, ammonium carbonate, potassium hydrogen carbonate, potassium carbonate, sodium hydrogen carbonate, sodium carbonate, methylamine, dimethylamine, trimethylamine, ethylamine, diethylamine, triethylamine, ethylenediamine, monoethanolamine, N-(β-aminoethyl)ethanolamine, hexamethylenediamine, diethylenetriamine, triethylenetetramine, anhydrous piperazine, piperazine hexahydrate, 1-(2-aminoethyl)piperazine, or N-methylpiperazine. In order to suppress metal contamination of the polished semiconductor substrate, the basic compound for use is preferably ammonia, an ammonium salt, an alkali metal hydroxide, an alkali metal salt, or quaternary ammonium hydroxide, more preferably ammonia, potassium hydroxide, sodium hydroxide, tetramethylammonium hydroxide, tetraethylammonium hydroxide, ammonium hydrogen carbonate, ammonium carbonate, potassium hydrogen carbonate, potassium carbonate, sodium hydrogen carbonate, or sodium carbonate, furthermore preferably ammonia, potassium hydroxide, sodium hydroxide, tetramethylammonium hydroxide, or tetraethylammonium hydroxide, and most preferably ammonia.

The polishing composition contains preferably not less than 0.001% by mass, and more preferably not less than 0.005% by mass of the basic compound. The more the amount of contained basic compound, the more enhanced becomes the rate of polishing a semiconductor substrate with the polishing composition.

The polishing composition contains preferably less than 0.4% by mass, and more preferably less than 0.25% by mass of the basic compound. The less the amount of contained basic compound, the smoother becomes the polished surface of a semiconductor substrate.

### <Silicon Dioxide>

Silicon dioxide optionally contained in the polishing composition has a function for mechanically polishing a semiconductor substrate.

The silicon dioxide for use is preferably colloidal silica or fumed silica, and more preferably colloidal silica. When colloidal silica or fumed silica is used, particularly when colloidal silica is used, scratches on the polished surface of a semiconductor substrate decrease.

The polishing composition contains preferably not less than 0.02% by mass, and more preferably not less than 0.04% by mass of silicon dioxide. The more the amount of contained silicon dioxide, the more enhanced becomes the rate of polishing a semiconductor substrate with the polishing composition.

The polishing composition contains preferably less than 5% by mass, and more preferably less than 1% by mass of silicon dioxide. The less the amount of contained silicon dioxide, the more enhanced becomes the dispersion stability of the polishing composition.

### <Water-Soluble Polymer>

A water-soluble polymer optionally contained in the polishing composition has functions for buffering the surface of a semiconductor substrate from physical polishing action and providing the semiconductor substrate surface with wettability, or in other words, improving the hydrophilic property of the surface.

The water-soluble polymer for use is preferably a cellulose derivative such as hydroxyethyl cellulose, or polyvinyl alcohol, polyvinyl pyrrolidone, or pullulan. A water-soluble cellulose derivative, in particular hydroxyethyl cellulose is preferred since it is excellent in imparting wettability to the surface of a semiconductor substrate and can be easily washed off the surface of a semiconductor substrate without remaining thereon.

The cellulose derivative for use as a water-soluble polymer has a weight-average molecular weight of preferably not less than 100,000, more preferably not less than 150,000, and most preferably not less than 200,000. The higher the weight-average molecular weight, the more enhanced becomes the functions of the cellulose derivative. That is, the functions are enhanced for buffering the surface of a semiconductor substrate from physical polishing action and providing the semiconductor substrate surface with wettability.

The cellulose derivative for use as a water-soluble polymer has a weight-average molecular weight of preferably less than 2,000,000, more preferably less than 1,000,000, and most preferably less than 700,000. The lower the weight-average molecular weight, the more enhanced becomes the dispersion stability of the polishing composition.

The polishing composition contains preferably not less than 0.001% by mass, and more preferably not less than 0.002% by mass of the water-soluble polymer. The more the amount of contained water-soluble polymer, the more enhanced become the above functions of the water-soluble polymer. That is, the functions are enhanced for buffering the surface of a semiconductor substrate from physical polishing action and providing the semiconductor substrate surface with wettability.

The polishing composition contains preferably less than 0.2% by mass, and more preferably less than 0.1% by mass of the water-soluble polymer. The less the amount of contained water-soluble polymer, the more enhanced becomes the dispersion stability of the polishing composition.

When the surface of a semiconductor substrate is polished using the polishing composition, the polishing composition is supplied to the semiconductor substrate surface, and concurrently the semiconductor substrate and a polishing pad pressed against the semiconductor substrate surface are rotated. When this is done, the semiconductor substrate surface is polished by physical action due to friction between the polishing pad and the semiconductor substrate surface (including physical action due to friction between silicon dioxide and the semiconductor substrate surface when the polishing composition contains silicon dioxide) and by chemical action due to the basic compound.

The present embodiment has the following advantages.

The polishing composition of the present embodiment contains a nonionic active agent with a molecular weight of 1,000 or more and less than 100,000 and an HLB value of not less than 17. Due to the function of the nonionic active agent, the surface haze of a polished semiconductor substrate is reduced. In addition, the nonionic active agent suppresses adhesion of particles to the polished surface of the semiconductor substrate. Consequently, the polishing composition can be suitably used in polishing the surface of semiconductor substrates, particularly in finish polishing of the surface of semiconductor substrates.

The above embodiment may be modified as described below.

The polishing composition of the above embodiment may contain two or more nonionic active agents.

The polishing composition of the above embodiment may contain two or more basic compounds.

The polishing composition of the above embodiment may contain two or more types of silicon dioxide.

The polishing composition of the above embodiment may contain two or more water-soluble polymers.

The polishing composition of the above embodiment may further contain a chelating agent. The contained chelating agent suppresses metal contamination of the polished semiconductor substrate. Examples of usable chelating agents include aminocarboxylic acid chelating agents and organic phosphonic acid chelating agents. Examples of aminocarboxylic acid chelating agents include ethylenediaminetetraacetic acid, sodium ethylenediaminetetraacetate, nitrilotriacetic acid, sodium nitrilotriacetate, ammonium nitrilotriacetate, hydroxyethyl ethylenediaminetriacetic acid, sodium hydroxyethyl ethylenediaminetriacetate, diethylenetriaminepentaacetic acid, sodium diethylenetriaminepentaacetate, triethylenetetraaminehexaacetic acid, and sodium triethylenetetraaminehexaacetate. Examples of organic phosphonic acid chelating agents include 2-aminoethylphosphonic acid, 1-hydroxyethylidene-1,1-diphosphonic acid, aminotri(methylenephosphonic acid), ethylenediaminetetrakis(methylenephosphonic acid), diethylenetriaminepenta(methylenephosphonic acid), ethane-1,1-diphosphonic acid, ethane-1,1,2-triphosphonic acid, ethane-1-hydroxy-1,1-diphosphonic acid, ethane-1-hydroxy-1,1,2-triphosphonic acid, ethane-1,2-dicarboxy-1,2-diphosphonic acid, methanehydroxy phosphonic acid, 2-phosphonobutane-1,2-dicarboxylic acid, 1-phosphonobutane-2,3,4-tricarboxylic acid, and α-methyl phosphonosuccinic acid. The preferred chelating agents are organic phosphonic acid chelating agents, in particular ethylenediaminetetrakis(methylenephosphonic acid) and diethylenetriaminepenta(methylenephosphonic acid). The most preferred is ethylenediaminetetrakis(methylenephosphonic acid).

The polishing composition of the above embodiment may further contain a known additive such as an antiseptic.

The polishing composition of the above embodiment may be of a one-component type or a multi-component type such as a two-component type.

The polishing composition of the above embodiment may be concentrated at the time of manufacturing or delivery. That means the polishing composition of the above embodiment may be manufactured and delivered in the form of liquid concentrate.

The polishing composition of the above embodiment may be prepared by diluting liquid concentrate of the polishing composition with water.

The polishing pad used in the polishing method using the polishing composition of the above embodiment is not specifically limited, and may be of nonwoven fabrics or suede, containing or not containing abrasive grains.

Examples and Comparative Examples of the present invention will now be described below.

The polishing compositions of Examples 1 to 12 and Comparative Examples 1 to 10 were prepared by blending all or some of a nonionic active agent, a basic compound, colloidal silica, and hydroxyethyl cellulose into ion-exchanged water. Details of the nonionic active agents and basic compounds in the polishing compositions of Examples 1 to 12 and Comparative Examples 1 to 10 are shown in Table 1. Each of the polishing compositions of Examples 1 to 12 and Comparative Examples 1 to 10 contained 0.5% by mass of colloidal silica and 0.02% by mass of hydroxyethyl cellulose with a weight-average molecular weight of 250,000, although this is not shown in Table 1. The colloidal silica for use had a mean particle diameter of 35 nm measured with FlowSorb II 2300 made by Micromeritics Instrument Corporation, and a mean particle diameter of 70 nm measured with N4 Plus Submicron Particle Sizer made by Beckman Coulter, Inc. Each of the polishing compositions of Examples 1 to 12 and Comparative Examples 1 to 4 and 6 to 10 contained 0.2% by mass of a basic compound. Iron, nickel, copper, chromium, and zinc contents in each of the polishing compositions of Examples 1 to 12 and Comparative Examples 1 to 10 were measured. As a result, the total contents were not higher than 0.1 ppm.

Using the polishing compositions of Examples 1 to 12 and Comparative Examples 1 to 10, the surface of silicon wafers were respectively polished under the conditions described in Table 2. The silicon wafers for use had a diameter of 300 mm, conductivity of p-type, a crystal orientation of <100>, and a resistivity of 0.1 Ωcm or more and less than 100 Ωcm. Prior to the use, the wafers were preliminarily polished with polishing slurry (under the trade name of GLANZOX 1103) made by Fujimi Incorporated.

Using wafer inspection equipment “Surfscan SP2” made by KLA Tencor Corporation, the number of particles having a size not smaller than 37 nm existing on the polished surface of each silicon wafer was counted. The counted number of particles of less than 70 was rated as excellent, 70 or more and less than 100 as good, 100 or more and less than 200 as slightly poor, and not less than 200 as poor. The results are shown in the column “Particles” of Table 1.

Using the wafer inspection equipment “Surfscan SP2” in DWO mode, a haze level of the polished surface of each silicon wafer was measured. The results of assessment based on the measured haze levels are shown in the column “Haze” of Table 1. In the column, the measured haze level of less than 0.10 ppm was rated as excellent, 0.10 ppm or more and less than 0.15 ppm as good, 0.15 ppm or more and less than 0.20 ppm as slightly poor, and not less than 0.20 ppm as poor.

TABLE 1

| | Nonionic active agent | | | | | | | |
|---|---|---|---|---|---|---|---|---|
| | | | | Ratio of | Nonionic active | | | |
| | | | | oxyethylene in | agent content in | | | |
| | | Molecular | HLB | nonionic active agent | polishing composition | Basic | | |
| | Type | weight | value | (% by mass) | (% by mass) | compound | Particles | Haze |
| Ex. 1 | POE | 80,000 | 20.0 | 100 | 0.003 | Ammonia | Good | Excellent |
| Ex. 2 | POE | 9,000 | 20.0 | 100 | 0.0001 | Ammonia | Excellent | Good |
| Ex. 3 | POE | 9,000 | 20.0 | 100 | 0.001 | Ammonia | Excellent | Excellent |
| Ex. 4 | POE | 9,000 | 20.0 | 100 | 0.003 | Ammonia | Excellent | Excellent |
| Ex. 5 | POE | 9,000 | 20.0 | 100 | 0.01 | Ammonia | Excellent | Excellent |
| Ex. 6 | POE | 9,000 | 20.0 | 100 | 0.03 | Ammonia | Good | Excellent |
| Ex. 7 | POE | 2,000 | 20.0 | 100 | 0.003 | Ammonia | Excellent | Good |
| Ex. 8 | POE-POP | 1,000 | 17.0 | 85 | 0.003 | Ammonia | Good | Good |
| Ex. 9 | POE-POP | 4,000 | 17.0 | 85 | 0.003 | Ammonia | Good | Excellent |
| Ex. 10 | POE-POP | 9,000 | 17.0 | 85 | 0.003 | Ammonia | Good | Excellent |
| Ex. 11 | POE-POP | 9,000 | 18.0 | 90 | 0.003 | Ammonia | Excellent | Excellent |
| Ex. 12 | POE-POB | 4,000 | 17.0 | 85 | 0.003 | Ammonia | Good | Good |
| Com. Ex. 1 | POE | 200,000 | 20.0 | 100 | 0.003 | Ammonia | Poor | Excellent |
| Com. Ex. 2 | POE | 600 | 20.0 | 100 | 0.003 | Ammonia | Excellent | Poor |
| Com. Ex. 3 | POE | 9,000 | 20.0 | 100 | 0.00001 | Ammonia | Excellent | Poor |
| Com. Ex. 4 | POE | 9,000 | 20.0 | 100 | 0.1 | Ammonia | Slightly | Slightly |
| | | | | | | | poor | poor |
| Com. Ex. 5 | POE | 9,000 | 20.0 | 100 | 0.003 | None | Poor | Slightly |
| | | | | | | | | poor |
| Com. Ex. 6 | POE-POP | 3,000 | 8.0 | 40 | 0.003 | Ammonia | Poor | Good |
| Com. Ex. 7 | POE-POP | 2,300 | 2.4 | 12 | 0.003 | Ammonia | Poor | Good |
| Com. Ex. 8 | POE-POP | 2,000 | 0.4 | 2 | 0.003 | Ammonia | Poor | Good |
| Com. Ex. 9 | POE-POP | 9,000 | 16.0 | 80 | 0.003 | Ammonia | Slightly | Excellent |
| | | | | | | | poor | |
| Com. Ex. 10 | POESML | 3,000 | 16.7 | 88 | 0.003 | Ammonia | Slightly | Good |
| | | | | | | | poor | |

Note:
“POE” represents polyoxyethylene.
“POE-POP” represents polyoxyethylene-polyoxypropylene glycol.
“POE-POB” represents polyoxyethylene-polyoxybutylene glycol.
“POESML” represents polyoxyethylene sorbitan monolaurate.

TABLE 2
Polishing machine: Single wafer polishing machine PNX-332B made by
Okamoto Machine Tool Works, Ltd.
Polishing pressure: 15 kPa
Revolution of surface plate: 30 rpm
Revolution of head: 30 rpm
Polishing time: 4 min.
Temperature of polishing composition: 20° C.
Feed rate of polishing composition: 0.5 liter/min. (continuously fed
without being circulated)

As shown in Table 1, in Examples 1 to 12, the assessment was rated as excellent or good in both “particles” and “haze”, which is satisfactory for practical use. In contrast, in Comparative Examples 1 to 10, the assessment was rated as poor or slightly poor in at least one of “particles” and “haze”, which is not satisfactory for practical use.

1. A polishing composition comprising a nonionic active agent with a molecular weight of 1,000 or more and less than 100,000 and an HLB value of not less than 17, a basic compound, and water.

2. The polishing composition according to claim 1, wherein the molecular weight of the nonionic active agent is 3,000 or more and less than 50,000.

3. The polishing composition according to claim 1, wherein the HLB value of the nonionic active agent is not less than 18.

4. The polishing composition according to claim 1, wherein the nonionic active agent is an oxyalkylene homopolymer or a copolymer of different oxyalkylenes.

5. The polishing composition according to claim 2, wherein the oxyalkylene homopolymer or the copolymer of different oxyalkylenes contains oxyethylene units in a proportion of not less than 85% by mass.

6. The polishing composition according to claim 5, wherein the oxyethylene units are contained in the oxyalkylene homopolymer or the copolymer of different oxyalkylenes in a proportion of not less than 90% by mass.

7. The polishing composition according to claim 4, wherein the nonionic active agent is polyoxyethylene, polyethylene glycol, polyoxypropylene, polyoxybuthylene, polyoxyethylene-polyoxypropylene glycol, or polyoxyethylene-polyoxybuthylene glycol.

8. The polishing composition according to claim 1, wherein the basic compound is ammonia, potassium hydroxide, sodium hydroxide, tetramethylammonium hydroxide, tetraethylammonium hydroxide, ammonium hydrogen carbonate, ammonium carbonate, potassium hydrogen carbonate, potassium carbonate, sodium hydrogen carbonate, sodium carbonate, methylamine, dimethylamine, trimethylamine, ethylamine, diethylamine, triethylamine, ethylenediamine, monoethanolamine, N-(β-aminoethyl)ethanolamine, hexamethylenediamine, diethylenetriamine, triethylenetetramine, anhydrous piperazine, piperazine hexahydrate, 1-(2-aminoethyl)piperazine, or N-methylpiperazine.

9. The polishing composition according to claim 1, further comprising silicon dioxide.

10. The polishing composition according to claim 9, wherein the silicon dioxide is colloidal silica.

11. The polishing composition according to claim 1, further comprising a water-soluble polymer.

12. The polishing composition according to claim 11, wherein the water-soluble polymer is a water-soluble cellulose derivative.

13. The polishing composition according to claim 12, wherein the water-soluble cellulose derivative has a weight-average molecular weight of not less than 100,000.

14. The polishing composition according to claim 11, wherein the water-soluble polymer is hydroxyethyl cellulose.

15. A polishing composition comprising:
a nonionic active agent with a molecular weight of 1,000 or more and less than 100,000 and an HLB value of not less than 17, the nonionic active agent being an oxyalkylene homopolymer or a copolymer of different oxyalkylenes that contains oxyethylene units in a proportion of not less than 85% by mass;
a basic compound;
silicon dioxide;
a water-soluble polymer; and
water.

16. A method of processing a semiconductor substrate, the method comprising:
preparing a polishing composition containing a nonionic active agent with a molecular weight of 1,000 or more and less than 100,000 and an HLB value of not less than 17, a basic compound, and water; and
polishing a surface of the semiconductor substrate using the polishing composition.

17. The method according to claim 16, wherein the nonionic active agent is an oxyalkylene homopolymer or a copolymer of different oxyalkylenes.

18. The method according to claim 17, wherein the oxyalkylene homopolymer or the copolymer of different oxyalkylenes contains oxyethylene units in a proportion of not less than 85% by mass.

19. The method according to claim 16, further comprising adding silicon dioxide to the polishing composition prior said polishing.

20. The method according to claim 16, further comprising adding a water-soluble polymer to the polishing composition prior to said polishing.
